(19) United States
(12) Patent Application Publication
(10) Pub. No.: US 2026/0114221 A1
(43) Pub. Date: Apr. 23, 2026

(54) PROTECTIVE TAPE PEELING APPARATUS AND PROTECTIVE TAPE PEELING METHOD

(71) Applicant: Samsung Electronics Co., Ltd., Suwon-si (KR)

(72) Inventors: Jaeil JEONG, Suwon-si (KR); Jwahyeon KIM, Suwon-si (KR); Seonggi JEON, Suwon-si (KR)

(73) Assignee: Samsung Electronics Co., Ltd., Suwon-si (KR)

(21) Appl. No.: 19/264,058

(22) Filed: Jul. 9, 2025

(30) Foreign Application Priority Data
Oct. 23, 2024 (KR) 10-2024-0146037

(51) Int. Cl. H01L 21/67; H01L 21/683

(52) U.S. Cl. CPC H10P 72/0442; H10P 72/7402; H10P 72/7412; H10P 72/7416; H10P 72/7422; H10P 72/7444

(57) ABSTRACT

A protective tape peeling apparatus may include a support table to support wafers having respective protective tapes attached thereto; a roller holder having an upper pinch roller and a lower pinch roller to move the protective tape peeled off from a wafer therebetween; an attachment portion to attach one end of the protective tape between the upper and lower pinch rollers to a first protective tape attached to a first wafer on the support table, and attach one end of the first protective tape between the upper pinch roller and the lower pinch roller to a second protective tape attached to a second wafer on the support table; and a reversing guide to reverse a non-adhesive surface of one end of the first protective tape between the upper and lower pinch rollers to face the support table when the roller holder moves from a first position to a second position.

### PRIORITY STATEMENT

This application claims priority under 35 U.S. C. § 119 to Korean Patent Application No. 10-2024-0146037, filed on Oct. 23, 2024 in the Korean Intellectual Property Office (KIPO), the contents of which are herein incorporated by reference in their entirety.

### BACKGROUND

### 1. Field

Example embodiments relate to a protective tape peeling apparatus and a protective tape peeling method. More particularly, example embodiments relate to an apparatus for peeling off a protective tape attached to one surface of a wafer and a method of peeling off a protective tape using the same.

### 2. Description of the Related Art

In manufacturing a semiconductor package, a lamination tape as a protective tape for protecting a circuit pattern may be attached on a front surface, e.g., an active surface of a wafer, and then a grinding process such as a back lap may be performed on a backside surface of the wafer. Then, the backside surface of the wafer may be attached to a dicing tape attached to a ring frame by an adhesive film such as DAF, and the lamination tape may be peeled off from the front surface of the wafer, and then the wafer may be diced to be individualized into a plurality of semiconductor chips.

Here, in order to peel the lamination tape from the wafer, a rectangular-shaped (e.g., having a long side length of 10 cm) peeling tape accessory may be attached to one end of the lamination tape by a heat fusion method, and a peeling apparatus may pull the peeling tape accessory to perform a peeling operation. The peeled lamination tape may be discarded after loading, and there are problems in that costs of the peeling tape accessories are incurred and it may be difficult to automate the peeling operation.

### SUMMARY

Some example embodiments provide a protective tape peeling apparatus that is able to reduce costs and/or improve productivity.

Some example embodiments provide a method of peeling a protective tape using the protective tape peeling apparatus.

According to an example embodiment, a protective tape peeling apparatus may include a support table configured to support wafers to which respective protective tapes are attached, the support table being configured for the wafers to be sequentially loaded on the support table; a roller holder configured to be reciprocally moved between a first position on a first side of the support table and a second position on a second side of the support table, the second side of the support table being opposite the first side of the support table, the roller holder having an upper pinch roller and a lower pinch roller for moving a protective tape peeled off from a wafer between the upper pinch roller and the lower pinch roller; an attachment portion configured to attach one end portion of a protective tape from between the upper pinch roller and the lower pinch roller to a first protective tape attached to a first wafer on the support table when the roller holder is at the first position, and configured to attach one end portion of the first protective tape from between the upper pinch roller and the lower pinch roller to a second protective tape attached to a second wafer on the support table when the roller holder is at the second position; and a reversing guide configured to reverse the one end portion of the first protective tape between the upper pinch roller and the lower pinch roller such that a non-adhesive surface of the first protective tape faces the support table when the roller holder moves from the first position to the second position.

According to an example embodiment, a protective tape peeling apparatus may include a support table configured to support wafers that are sequentially placed and to which respective protective tapes are attached on the wafers; a tape peeling portion including a roller holder having an upper pinch roller and a lower pinch roller configured to move a protective tape peeled from a previous wafer in a first direction, a first attachment portion configured to attach one end portion of the protective tape moving between the upper pinch roller and the lower pinch roller to one end portion of a first protective tape attached to a first wafer on the support table, and a second attachment portion configured to attach one end portion of the first protective tape peeled from the first wafer and moving between the upper pinch roller and the lower pinch roller to one end portion of a second protective tape attached to a second wafer on the support table; a reversing guide configured to reverse one end portion of the first protective tape peeled off from the first wafer such that a non-adhesive surface of one end portion of the first protective tape faces the support table; a first driving portion configured to reciprocally move the tape peeling portion between a first position on a first side of the support table and a second position on a second side of the support table, the second side of the support table being opposite the first side of the support table; and a second driving portion configured to move the reversing guide upward and downward on the second side of the support table.

According to an example embodiment, a method of peeling off a protective tape may include providing a roller holder having an upper pinch roller and a lower pinch roller configured to move a protective tape peeled from a wafer between the upper pinch roller and the lower pinch roller; placing a first wafer on a support table, the first wafer having a first protective tape attached thereto; attaching one end portion of the protective tape between the upper pinch roller and the lower pinch roller to the first protective tape attached to the first wafer at a first position on a first side of the support table; moving the protective tape between the upper pinch roller and the lower pinch roller to a second position on a second side of the support table, the second side of the support table being opposite the first side of the support table, to peel the first protective tape from the first wafer; when the protective tape is moved from the first position to the second position, reversing one end portion of the first protective tape between the upper pinch roller and the lower pinch roller such that a non-adhesive surface of the one end portion of the first protective tape faces the support table; placing a second wafer on the support table, the second wafer having a second protective tape attached thereto; attaching the one end portion of the first protective tape between the upper pinch roller and the lower pinch roller to the second protective tape attached to the second wafer at the second position; and moving the first protective tape between the upper pinch roller and the lower pinch roller to the first position to peel off the second protective tape from the second wafer.

In some embodiments, the attaching the one end portion of the protective tape to the first protective tape attached to the first wafer may include pressing the one end portion of the protective tape onto the one end portion of the first protective tape; and heating the one end portion of the protective tape to attach the one end portion of the protective tape and the one end portion of the first protective tape to each other in a heat fusion manner.

In some embodiments, the heating the one end portion of the protective tape may include using a heater or ultrasonic waves.

In some embodiments, the pressing the one end portion of the protective tape onto the one end portion of the first protective tape may include bringing the non-adhesive surface of the one end portion of the protective tape and a non-adhesive surface of the one end portion of the first protective tape into contact with each other.

In some embodiments, the reversing one end portion of the first protective tape between the upper pinch roller and the lower pinch roller may include raising a guide rod having a reversing guide surface of a concave curved shape to a reversing position above the second side of the support table; and sliding at least a portion of the first protective tape along the reversing guide surface.

In some embodiments, the attaching the one end portion of the first protective tape to the second protective tape attached to the second wafer may include pressing the one end portion of the first protective tape onto the one end portion of the second protective tape; and heating the one end portion of the first protective tape to attach the one end portion of the first protective tape and the one end portion of the second protective tape to each other in a heat fusion manner.

In some embodiments, the heating the one end portion of the first protective tape may include using a heater or ultrasonic waves.

In some embodiments, the pressing the one end portion of the first protective tape onto the one end portion of the second protective tape may include bringing the non-adhesive surface of the one end portion of the first protective tape and a non-adhesive surface of the one end portion of the second protective tape into contact with each other.

In some embodiments, the placing the first wafer or the second wafer on the support table may include attaching the first wafer or the second wafer on a dicing tape attached to a ring frame; and placing the ring frame on the support table.

According to example embodiments, a protective tape peeling apparatus may sequentially (or continuously) peel protective tapes attached to wafers that are sequentially provided on a support table, without using separate peeling tape accessories. A protective tape peeled off from a previous wafer may be attached to a new first protective tape to be peeled off, and the previously peeled protective tape may be pulled to peel the first protective tape from the first wafer, and successively, the first protective tape peeled off from the first wafer may be attached to a new second protective tape to be peeled off, and the peeled first protective tape may be pulled to peel the second protective tape from the second wafer. Accordingly, costs of the peeling tape accessories may be reduced, and/or productivity may be improved by (fully or more fully) automating the peeling operation.

According to an example embodiment, a method of manufacturing a semiconductor package may include attaching a protective tape over circuit elements on a first surface of a wafer; grinding a second surface of the wafer, the second surface of the wafer being opposite the first surface of the wafer; removing the protective tape from the first surface of the wafer; dicing the wafer into a plurality of semiconductor chips; and arranging two or more of the semiconductor chips on a package substrate. The removing protective tape from the first surface of the wafer may be performed using a protective tape peeling apparatus according to example embodiments. The protective tape peeling apparatus may include a support table, a roller holder configured to be reciprocally moved between a first position on a first side of the support table and a second position on a second side of the support table, an attachment portion, and a reversing guide. The second side of the support table may be opposite the first side of the support table. The roller holder may have an upper pinch roller and a lower pinch roller.

In some embodiments, the attachment portion may include a suction portion configured to apply suction to the one end portion of the protective tape; and a heater configured to heat the one end portion of the protective tape.

In some embodiments, the attachment portion may include a suction portion configured to apply suction to the one end portion of the protective tape; and an ultrasonic generator configured to heat to the one end portion of the protective tape.

In some embodiments, the protective tape peeling apparatus may further include a peeling guide roller configured to guide movement of the protective tape after the protective tape is peeled from the wafer and moves between the upper pinch roller and the lower pinch roller.

In some embodiments, the reversing guide may include a guide rod having a reversing guide surface of a concave curved shape for contacting at least a portion of the first protective tape moved between the upper pinch roller and the lower pinch roller.

### BRIEF DESCRIPTION OF THE DRAWINGS

Example embodiments will be more clearly understood from the following detailed description taken in conjunction with the accompanying drawings. FIGS. 1 to 30 represent non-limiting, example embodiments as described herein.

FIG. 1 is a cross-sectional view illustrating a protective tape peeling apparatus in accordance with example embodiments.

FIG. 2 is a perspective view illustrating the protective tape peeling apparatus of FIG. 1.

FIG. 3 is a cross-sectional view illustrating a ring frame on a support table of FIG. 1, wherein a wafer is supported on the ring frame.

FIG. 4 is an enlarged cross-sectional view illustrating portion ‘A’ in FIG. 3.

FIG. 5 is a cross-sectional view illustrating the protective tape peeling apparatus of FIG. 1, wherein a tape peeling portion is positioned at a first position.

FIG. 6 is an enlarged cross-sectional view illustrating the tape peeling portion of FIG. 5.

FIG. 7 is a cross-sectional view illustrating protective tapes adhered to each other at the first position of FIG. 5.

FIG. 8 is a perspective view illustrating a first adhering portion of FIG. 1.

FIG. 9 is a bottom view of the first adhering portion of FIG. 8.

FIG. 10A is a cross-sectional view illustrating a protective tape adsorbed by the first adhering portion of FIG. 8.

FIG. 10B is a cross-sectional view illustrating protective tapes adhered to each other by the first adhering portion of FIG. 8.

FIG. 11 is a cross-sectional view illustrating the protective tape peeling apparatus of FIG. 1, wherein the tape peeling portion is positioned at a second position.

FIG. 12 is an enlarged cross-sectional view illustrating the tape peeling portion of FIG. 11.

FIG. 13 is a cross-sectional view illustrating protective tapes adhered to each other at the second position of FIG. 11.

FIG. 14 is a perspective view illustrating a second adhering portion of FIG. 1.

FIG. 15 is a bottom view of the second adhering portion of FIG. 14.

FIG. 16A is a cross-sectional view illustrating a protective tape absorbed by the second adhering portion of FIG. 11.

FIG. 16B is a cross-sectional view illustrating protective tapes adhered to each other by the second adhering portion of FIG. 11.

FIG. 17 is a cross-sectional view illustrating the protective tape peeling apparatus of FIG. 1, wherein the tape peeling portion and a reversing guide are positioned at a reverse position.

FIGS. 18A, 19A, 20A, 21A, 22A, and 23A are cross-sectional views illustrating a method of peeling off protective tapes in accordance with example embodiments.

FIGS. 18B, 19B, 20B, 21B, 22B, and 23B are perspective views of FIGS. 18A, 19A, 20A, 21A, 22A, and 23A, respectively.

FIG. 24 is a flow chart illustrating a method of manufacturing a semiconductor package in accordance with example embodiments.

FIGS. 25 to 30 are views illustrating a substrate dicing method in accordance with example embodiments.

### DETAILED DESCRIPTION OF EXAMPLE EMBODIMENTS

Hereinafter, example embodiments will be explained in detail with reference to the accompanying drawings.

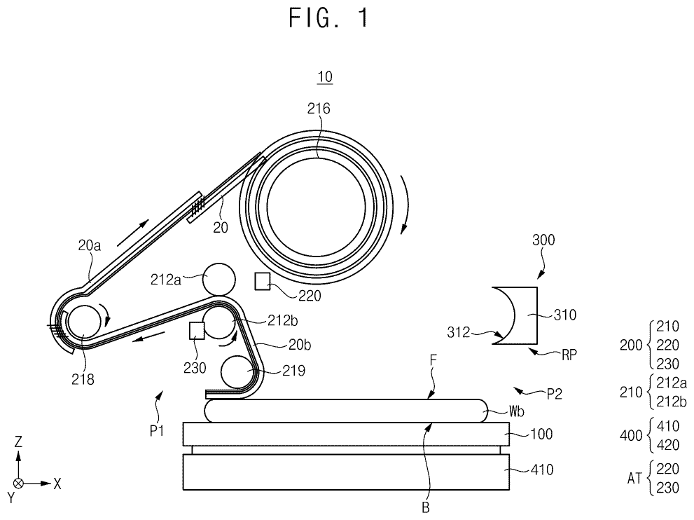

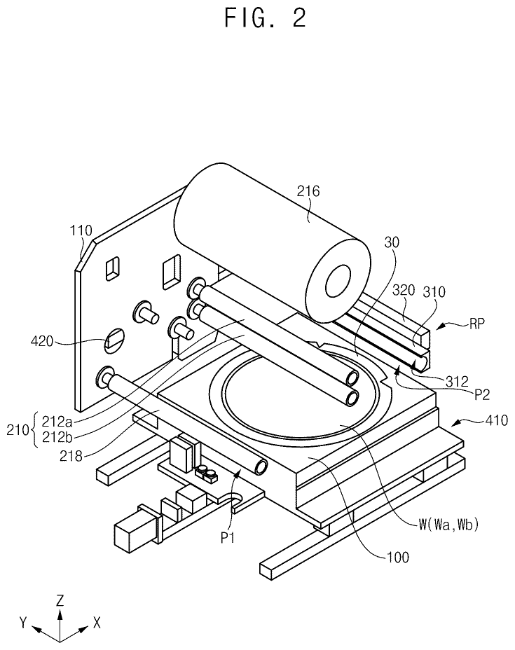

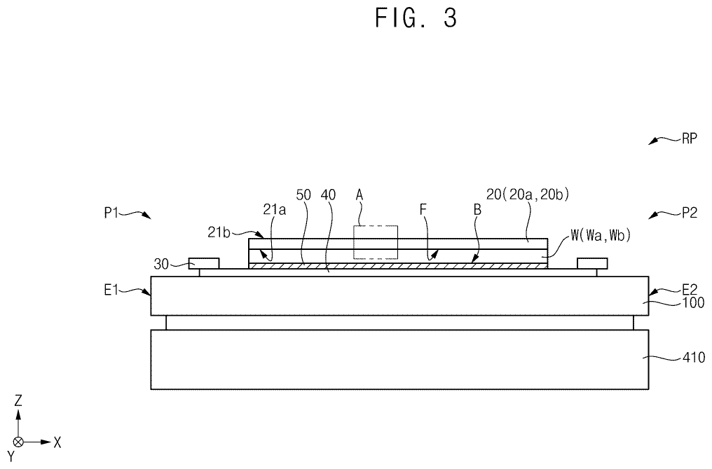

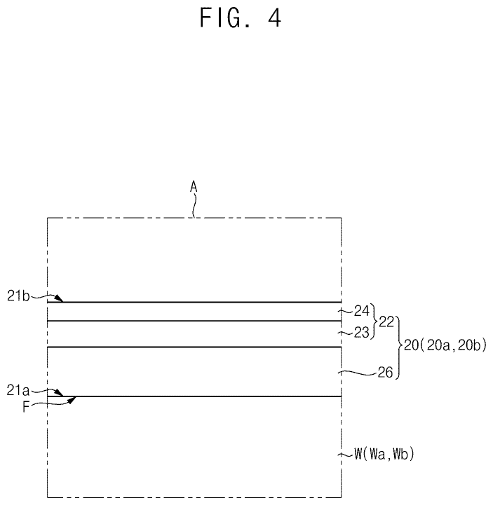

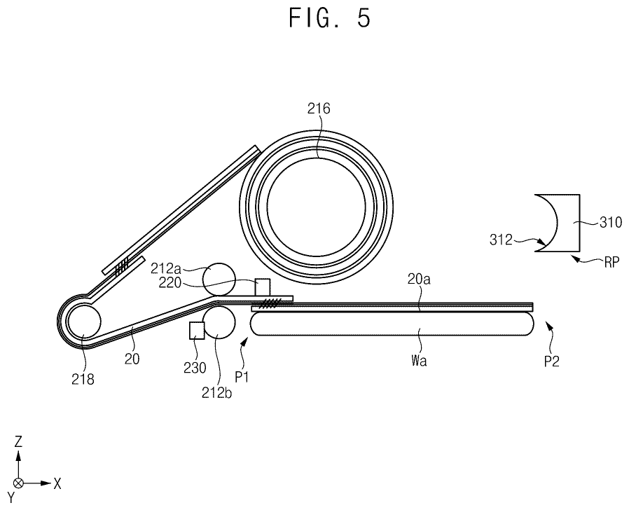

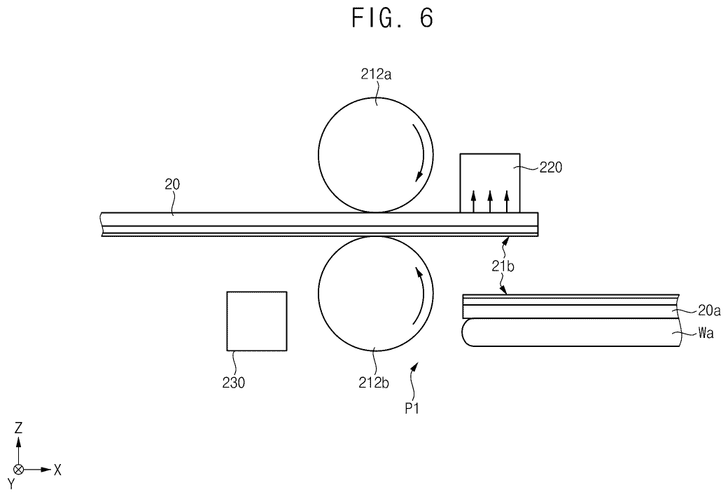

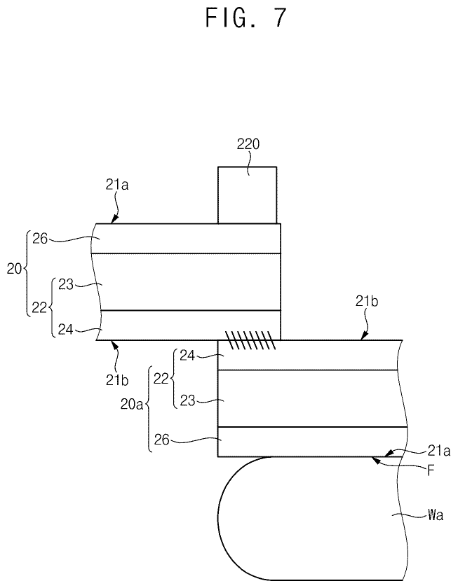

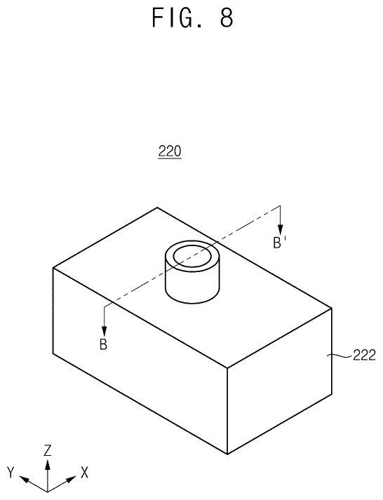

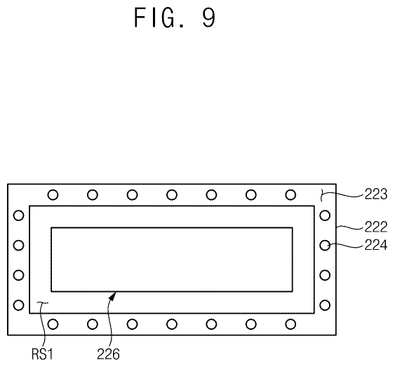

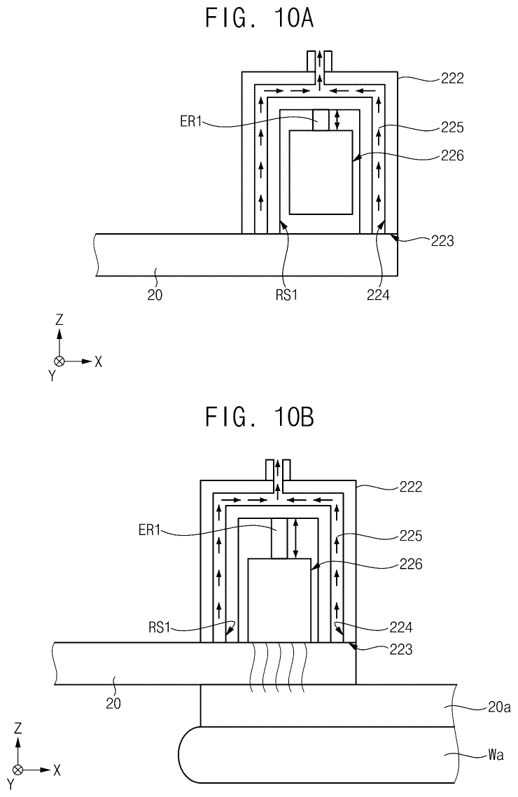

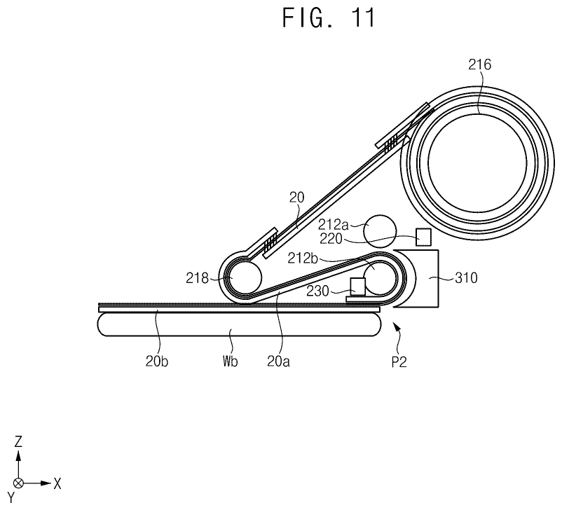

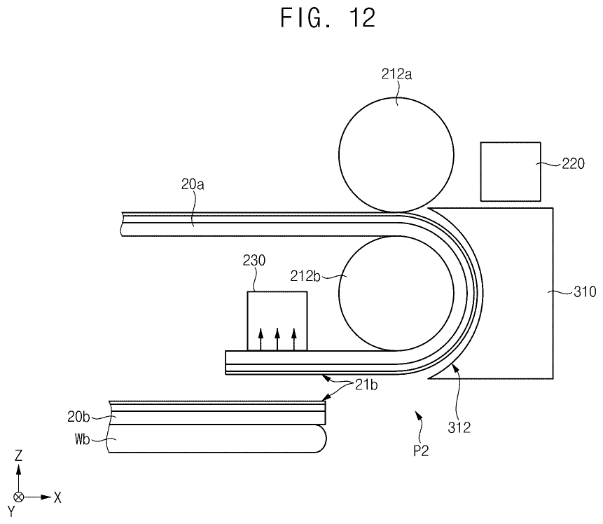

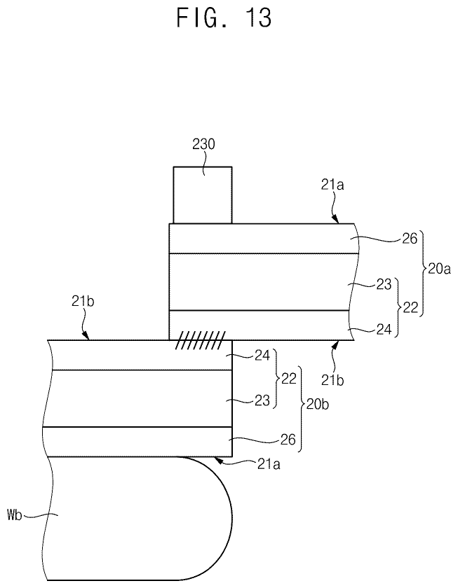

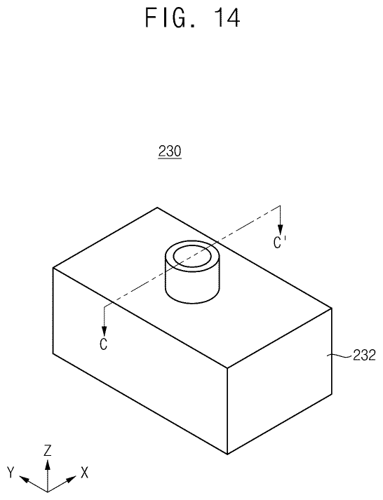

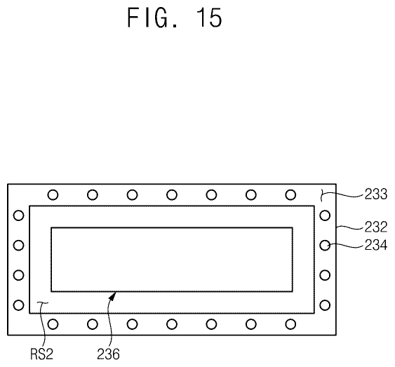

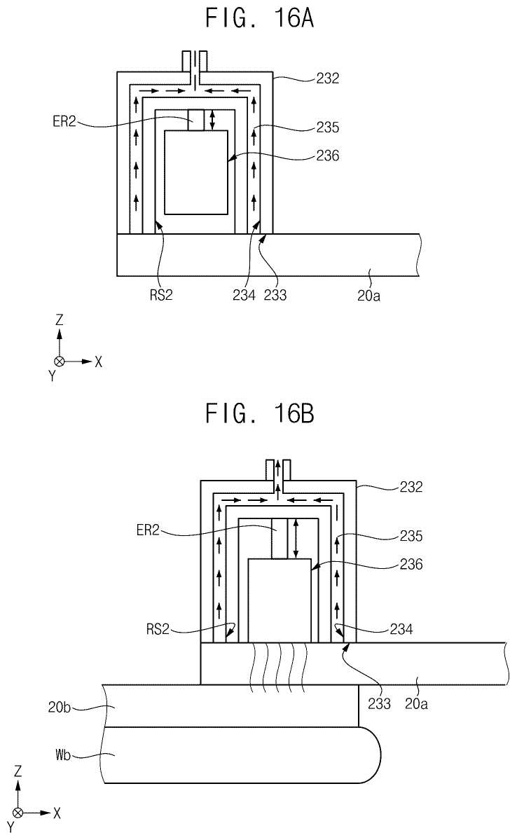

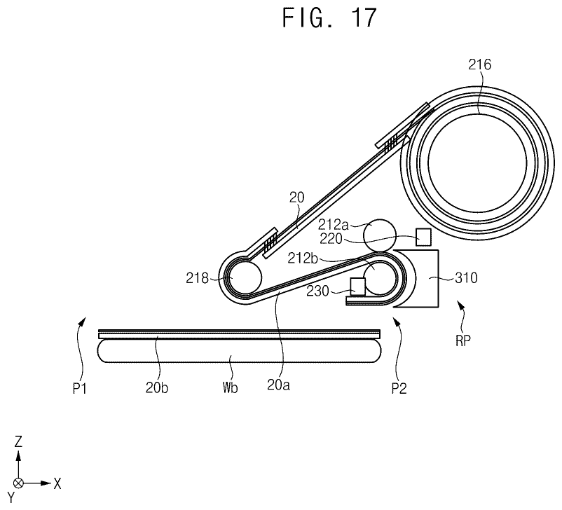

FIG. 1 is a cross-sectional view illustrating a protective tape peeling apparatus in accordance with example embodiments. FIG. 2 is a perspective view illustrating the protective tape peeling apparatus of FIG. 1. FIG. 3 is a cross-sectional view illustrating a ring frame on a support table of FIG. 1, wherein a wafer is supported on the ring frame. FIG. 4 is an enlarged cross-sectional view illustrating portion ‘A’ in FIG. 3. FIG. 5 is a cross-sectional view illustrating the protective tape peeling apparatus of FIG. 1, wherein a tape peeling portion is positioned at a first position. FIG. 6 is an enlarged cross-sectional view illustrating the tape peeling portion of FIG. 5. FIG. 7 is a cross-sectional view illustrating protective tapes adhered to each other at the first position of FIG. 5. FIG. 8 is a perspective view illustrating a first adhering portion of FIG. 1. FIG. 9 is a bottom view of the first adhering portion of FIG. 8. FIG. 10A is a cross-sectional view illustrating a protective tape adsorbed by the first adhering portion of FIG. 8, and FIG. 10B is a cross-sectional view illustrating protective tapes adhered to each other by the first adhering portion of FIG. 8. FIG. 11 is a cross-sectional view illustrating the protective tape peeling apparatus of FIG. 1, wherein the tape peeling portion is positioned at a second position. FIG. 12 is an enlarged cross-sectional view illustrating the tape peeling portion of FIG. 11. FIG. 13 is a cross-sectional view illustrating protective tapes adhered to each other at the second position of FIG. 11. FIG. 14 is a perspective view illustrating a second adhering portion of FIG. 1. FIG. 15 is a bottom view of the second adhering portion of FIG. 14. FIG. 16A is a cross-sectional view illustrating a protective tape absorbed by the second adhering portion of FIG. 11, and FIG. 16B is a cross-sectional view illustrating protective tapes adhered to each other by the second adhering portion of FIG. 11. FIG. 17 is a cross-sectional view illustrating the protective tape peeling apparatus of FIG. 1, wherein the tape peeling portion and a reversing guide are positioned at a reverse position. FIGS. 10A and 10B include cross-sectional portions cut along the line B-B′ in FIG. 8. FIGS. 16A and 16B include cross-sectional portions cut along the line C-C′ in FIG. 14.

Referring to FIGS. 1 to 17, a protective tape peeling apparatus 10 may include a support table 100, a tape peeling portion 200, and a reversing guide 300. In addition, the protective tape peeling apparatus 10 may further include a driving portion 400 connected to the support table 100, the tape peeling portion 200, and the reversing guide 300 to control their operations.

In example embodiments, the protective tape peeling apparatus 10 may be an apparatus for sequentially peeling off protective tapes 20, 20a, 20b respectively attached to wafers W, Wa, Wb that are sequentially provided on the support table 100. The protective tape peeling apparatus 10 may attach a protective tape 20 peeled from a previous wafer to a new first protective tape 20a to be peeled from a first wafer Wa, and pull the previously peeled protective tape 20 to peel the first protective tape 20a from the first wafer Wa. Sequentially, the protective tape peeling apparatus 10 may attach the first protective tape 20b peeled from the first wafer Wa to a new second protective tape 20b to be peeled from a second wafer Wb, and pull the peeled first protective tape 20b to peel the second protective tape 20b from the second wafer Wb.

As illustrated in FIGS. 3 and 4, a ring frame 30 on which a wafer W is placed may be disposed on the support table 100. For example, a protective tape 20 such as a lamination tape may be attached to a front surface of the wafer W, e.g., an active surface, to protect circuit patterns, and then a grinding process such as a back lap process may be performed on a backside surface of the wafer W. Then, the backside surface of the wafer W may be attached to a dicing tape 40 attached to the ring frame 30 by an adhesive film 50 such as a die attach film (DAF), the ring frame 30 may be provided on the support table 100, and then, as described below, the protective tape peeling apparatus 10 may remove the protective tape 20 from the front surface of the wafer W.

The driving portion 400 may include a first driving portion 410 configured to move the tape peeling portion 200 relative to the wafer W on the support table 100. In addition, the driving portion 400 may include a second driving portion 420 configured to move the reversing guide 300 relative to the wafer W on the support table 100.

The first driving portion 410 may include a table driving portion configured to move the support table 100 in X, Y, and Z directions. In particular, the support table 100 may be a movable table that supports the ring frame 30 and is movable in at least one direction. The support table 100 may be installed on the table driving portion so as to be movable in X and Y directions. The first driving portion 410 may include a driving mechanism (e.g., motor, robotic arm) for moving the support table 100, and the first driving portion 410 may move the support table 100 in X, Y, and Z directions according to a control signal of a controller. A movement speed of the support table 100 may be adjustable.

The second driving portion 420 may further include a reversing guide driving portion configured to move a guide rod 310 of the reversing guide 300 in X, Y, and Z directions. As described below, the reversing guide driving portion may move the guide rod 310 of the reversing guide 300 in X, Y, and Z directions. The second drive portion 420 may include a driving mechanism (e.g., motor, robotic arm).

For example, the substrate W, Wa, Wb may include a silicon wafer (Si Wafer), a silicon carbide wafer (SiC Wafer), a gallium arsenide wafer (GaAs Wafer), or a silicon single crystal wafer (Si-Single Crystal Wafer). A thickness of the substrate W, Wa, Wb may be within a range of 50 μm to 850 μm.

In example embodiments, the tape peeling portion 200 may include a mechanism for attaching a previously peeled protective tape 20, 20a to a new protective tape 20a, 20b to be peeled and for pulling the previously peeled protective tape 20, 20a. The tape peeling portion 200 may include a roller holder 210 and an attachment portion AT. The attachment portion AT may include a first attachment portion 220 and a second attachment portion 230.

In particular, the roller holder 210 may include an upper pinch roller 212a and a lower pinch roller 212b that moves the protective tape 20 in a first direction (-X direction) while sandwiching the protective tape 20 peeled from the previous wafer W. The upper pinch roller 212a and the lower pinch roller 212b may have a freely rotatable roll structure.

The upper pinch roller 212a and the lower pinch roller 212b may be installed on at least one support plate 110 that is parallel to a first horizontal direction (X direction) and extends in a vertical direction (Z direction). The upper pinch roller 212a and the lower pinch roller 212b may extend in a second horizontal direction (Y direction) on the support plate 110 respectively. One end portion of the upper pinch roller 212a may be connected to a first rotating shaft of a first support block provided on the support plate 110 and may be rotatable about a central axis of the upper pinch roller, and one end portion of the lower pinch roller 212b may be connected to a second rotating shaft of a second support block provided on the support plate 110 and may be rotatable about a central axis of the lower pinch roller.

The tape peeling portion 200 may further include a winding roller 216 for winding the protective tape 20 supplied from the roller holder 210 into a roll form. One end portion of the winding roller 216 may be connected to a rotating shaft of a driving motor installed on the support plate 110 and may be rotatable about a central axis of the winding roller. Accordingly, the protective tapes 20, 20a, 20b supplied from the roller holder 210 may be wound around the winding roller 216 and provided in a roll form.

In addition, the tape peeling portion 200 may further include a tension roller 218 for movement and tension of the protective tape 20 between the roller holder 210 and the winding roller 216. The tension roller 218 may have a structure in which the position is fixed or the position is adjustable depending on design specifications.

As illustrated in FIGS. 1 and 3, the roller holder 210 may be provided to be reciprocally movable between a first position P1 on a first side E1 of the support table 100 and a second position P2 on a second side E2 opposite to the first side E1 of the support table 100. The first position P1 and the second position P2 may represent relative positions between the roller holder 210 and the wafer on the support table 100. The roller holder 210 at the first position P1 may be adjacent to a first edge portion of the first wafer Wa on the support table 100, and the roller holder 210 at the second position P2 may be adjacent to a second edge portion of the second wafer Wb on the support table 100. The first edge portion and the second edge portion may be symmetrical to each other with respect to the center of the support table 100, that is, the center of the wafer. Here, the second wafer Wb may be referred to as a wafer loaded on the support table 100 immediately after the first protective tape 20a is peeled off from the first wafer Wa.

When the upper pinch roller 212a and the lower pinch roller 212b are installed so that their positions are fixed on the support plate 110, the first driving portion 410 may move the support table 100 in X, Y, and Z directions to move the wafer W on the support table 100 relative to the roller holder 210. In contrast, when the upper pinch roller 212a and the lower pinch roller 212b are installed so that their positions may be adjusted on the support plate 110, the upper pinch roller 212a, the lower pinch roller 212b, and the support table 100 may be provided to be movable in X, Y, and Z directions.

In example embodiments, the first attachment portion 220 may be arranged in a first side (e.g., a right side in a front view) of the roller holder 210 and may attach one end portion of the protective tape 20 between the upper pinch roller 212a and the lower pinch roller 212b to one end portion of the first protective tape 20a attached to the first wafer Wa on the support table 100. The first attachment portion 220 may attach one end portion of the protective tape 20 between the upper pinch roller 212a and the lower pinch roller 212b to the first protective tape 20a attached to the first wafer Wa to be peeled, when the roller holder 210 is at the first position P1.

As illustrated in FIGS. 5 to 10B, the first attachment portion 220 may include a first suction block 222 having first suction holes 224 formed therein. The first suction block 222 may extend in the second horizontal direction (Y direction) on the support plate 110. The first suction block 222 may be positioned in the right side of the roller holder 210. The first suction block 222 may be provided to be movable relative to the first wafer Wa on the support table 100.

The first suction holes 224 that function as a suction portion may be formed in a lower surface 223 of the first suction block 222. For example, several to several tens of first suction holes 224 may be respectively connected to a first air suction line 225 extending within the first suction block 222. A first vacuum pump may generate at least a partial vacuum in the first suction holes 224 through the first air suction line 225. By generating the at least a partial vacuum in the first suction holes 224, a portion of the lower surface 223 of the first suction block 222 may suction and support one end portion of the protective tape 20 between the upper pinch roller 212a and the lower pinch roller 212b. Alternatively, a first suction line may be formed in a form of a trench in the lower surface 223 of the first suction block 222 to extend in one direction and to be connected to the first air suction line 225, instead of the first suction holes. The first vacuum pump may generate at least a partial vacuum in the first suction line through the first air suction line 225.

The first attachment portion 220 may include a first heating block 226 that is accommodated in a first receiving space RS1 of the first suction block 222 and is configured to heat one end portion of the protective tape 20 suctioned on the lower surface 223. The first suction block 222 may have the first receiving space RS1 with an open lower portion, and the first heating block 226 may be arranged within the first receiving space RS1 so as to be movable up and down by a first lifting rod ER1. The first heating block 226 may include a first heater or a first ultrasonic generator therein.

As illustrated in FIGS. 10A and 10B, the first suction block 222 may move to the first position P1 together with the roller holder 210, and the first suction block 222 may move lower than the upper pinch roller 212a to suction one end portion of the protective tape 20 and press the suctioned one end portion of the protective tape 20 onto one end of the first protective tape 20a attached to the first wafer Wa on the support table 100. Then, the first heating block 226 may move downward within the first receiving space RS1 of the first suction block 222 to contact and heat one end portion of the protective tape 20, thereby attaching one end portion of the protective tape 20 and one end portion of the first protective tape 20a to each other in a heat fusion manner.

The protective tape 20, 20a, 20b may include a base film 22 and an adhesive layer 26 provided on the base film 22. The base film 22 may include a transparent carrier layer 23 and a release film layer 24. For example, the adhesive layer 26 may include a pressure sensitive adhesive PSA. The adhesive layer 26 may include polyethylene PE. The release film layer 24 may include oriented polypropylene OPP. When the adhesive layer 26 is irradiated with ultraviolet rays, the adhesive strength of the adhesive layer 26 may be weakened.

The protective tape 20, 20a, 20b may have an adhesive surface 21a and a non-adhesive surface 21b opposite to the adhesive surface 21a. The adhesive surface 21a may be attached on the active surface of the wafer W, Wa, Wb. When the protective tape 20, 20a, 20b is attached on the active surface of the wafer W, Wa, Wb, the non-adhesive surface 21b of the protective tape 20, 20a, 20b may be exposed to the outside.

As illustrated in FIG. 7, when the roller holder 210 is at the first position P1, the first attachment portion 220 may press one end portion of the suctioned protective tape 20 onto one end portion of the first protective tape 20a attached to the first wafer Wa on the support table 100. At this time, the non-adhesive surface 21b of one end portion of the protective tape 20 may come into contact with the non-adhesive surface 21b of one end portion of the first protective tape 20a attached to the first wafer Wa on the support table 100. When the non-adhesive surface 21b of one end portion of the protective tape 20 and the non-adhesive surface 21b of one end portion of the first protective tape 20a are in contact with each other, they may be heated by the first heating block 226 to have an adhesive strength, so that one end portion of the protective tape 20 and one end portion of the first protective tape 20a may be attached to each other in a heat fusion manner.

When the first heating block 226 includes the first heater therein, the first heater may heat one end portion of the protective tape 20 suctioned on the lower surface 223 of the first suction block 222, so that one end portion of the protective tape 20 and one end portion of the first protective tape 20a may be attached to each other in a heat fusion manner. The first heater may include a heating circuit, an infrared heater, or other suitable heating device.

When the first heating block 226 includes the first ultrasonic generator therein, the first ultrasonic generator may include an ultrasonic vibrator. Ultrasonic waves generated from the ultrasonic vibrator may be used to heat one end portion of the protective tape 20 suctioned on the lower surface 223 of the first suction block 222. The ultrasonic waves generated from the first ultrasonic generator may be transmitted through the lower surface 223 of the first suction block 222 to attach one end portion of the protective tape 20 and one end portion of the first protective tape 20a to each other in a heat fusion manner.

After one end portion of the protective tape 20 between the upper pinch roller 212a and the lower pinch roller 212b is attached to one end portion of the first protective tape 20a attached to the first wafer Wa on the support table 100 by the first attachment portion 220, the roller holder 210 may move from the first position P1 to the second position P2, thereby pulling the previously peeled protective tape 20 to peel the first protective tape 20a from the first wafer Wa. As the roller holder 210 approaches the second position P2, the peeled first protective tape 20a may move between the upper pinch roller 212a and the lower pinch roller 212b, and then may be wound around the winding roller 216.

In example embodiments, the second attachment portion 230 may be arranged in a second side (e.g., a left side in a front view) of the roller holder 210 and may attach one end portion of the first protective tape 20a between the upper pinch roller 212a and the lower pinch roller 212b to one end portion of the second protective tape 20b attached to the second wafer Wb on the support table 100. The second attachment portion 230 may attach one end portion of the first protective tape 20a between the upper pinch roller 212a and the lower pinch roller 212b to the second protective tape 20b attached to the second wafer Wb to be peeled, when the roller holder 210 is at the second position P1.

As illustrated in FIGS. 11 to 16B, the second attachment portion 230 may include a second suction block 232 having second suction holes 234 formed therein. The second suction block 232 may extend in the second horizontal direction (Y direction) on the support plate 110. The second suction block 232 may be positioned in the left side of the roller holder 210. The second suction block 232 may be provided to be movable relative to the second wafer Wb on the support table 100.

The second suction holes 234 that function as a suction portion may be formed in a lower surface 233 of the second suction block 232. For example, several to several tens of second suction holes 234 may be respectively connected to a second air suction line 235 extending within the second suction block 232. A second vacuum pump may generate at least a partial vacuum in the second suction holes 234 through the second air suction line 235. By generating the at least a partial vacuum in the second suction holes 234, a portion of the lower surface 233 of the second suction block 232 may suction and support one end portion of the first protective tape 20a between the upper pinch roller 212a and the lower pinch roller 212b. Alternatively, a second suction line may be formed in a form of a trench in the lower surface 233 of the second suction block 232 to extend in one direction and to be connected to the second air suction line 235, instead of the second suction holes. The second vacuum pump may generate at least a partial vacuum in the second suction line through the second air suction line 235.

The second attachment portion 230 may include a second heating block 236 that is accommodated in a second receiving space RS2 of the second suction block 232 and is configured to heat one end portion of the first protective tape 20a suctioned on the lower surface 233. The second suction block 232 may include the second receiving space RS2 with an open lower portion, and the second heating block 236 may be arranged within the second receiving space RS2 so as to be movable up and down by a second lifting rod ER2. The second heating block 236 may include a second heater or a second ultrasonic generator therein.

As illustrated in FIG. 16A and FIG. 16B, the second suction block 232 may move to the second position P2 together with the roller holder 210, and the second suction block 232 may move lower than the lower pinch roller 212b to suction one end portion of the first protective tape 20a and press the suctioned one end portion of the first protective tape 20a onto one end portion of the second protective tape 20b attached to the second wafer Wb on the support table 100. Then, the second heating block 236 may move downward within the second receiving space RS2 of the second suction block 232 to contact and heat one end portion of the first protective tape 20a, thereby attaching one end portion of the first protective tape 20a and one end portion of the second protective tape 20b to each other in a heat fusion manner.

As illustrated in FIG. 13, when the roller holder 210 is at the second position P2, the second attachment portion 230 may press one end portion of the suctioned first protective tape 20a onto one end portion of the second protective tape 20b attached to the second wafer Wb on the support table 100. At this time, a non-adhesive surface 21b of one end portion of the first protective tape 20a may come into contact with a non-adhesive surface 21b of one end portion of the second protective tape 20b attached to the second wafer Wb on the support table 100. When the non-adhesive surface 21b of one end portion of the first protective tape 20a and the non-adhesive surface 21b of one end portion of the second protective tape 20b are in contact with each other, they may be heated by the second heating block 236 to have an adhesive strength, so that one end portion of the first protective tape 20a and one end portion of the second protective tape 20b may be attached to each other in a heat fusion manner.

When the second heating block 236 includes the second heater therein, the second heater may heat one end portion of the first protective tape 20a suctioned on the lower surface 233 of the second suction block 232 to attach one end portion of the first protective tape 20a and one end portion of the second protective tape 20b to each other in a heat fusion manner.

When the second heating block 236 includes the second ultrasonic generator therein, the second ultrasonic generator may include an ultrasonic vibrator. Ultrasonic waves generated from the ultrasonic vibrator may be used to heat one end portion of the first protective tape 20a suctioned on the lower surface 233 of the second suction block 232. The ultrasonic waves generated from the second ultrasonic generator may be transmitted through the lower surface 233 of the second suction block 232 to attach one end portion of the first protective tape 20a and one end portion of the second protective tape 20b to each other in a heat fusion manner.

After one end portion of the first protective tape 20a between the upper pinch roller 212a and the lower pinch roller 212b is attached to one end portion of the second protective tape 20b attached to the second wafer Wb on the support table 100 by the second attachment portion 230, the roller holder 210 may move from the second position P2 to the first position P1, thereby pulling the first protective tape 20a to peel the second protective tape 20b from the second wafer Wb. As the roller holder 210 approaches the first position P1, the peeled second protective tape 20b may move between the upper pinch roller 212a and the lower pinch roller 212b, and then may be wound around the winding roller 216.

In example embodiments, the reversing guide 300 may reverse one end portion of the first protective tape 20a between the upper pinch roller 212a and the lower pinch roller 212b such that the non-adhesive surface 21b of the first protective tape 20a faces the support table 100 when the roller holder 210 moves from the first position P1 to the second position P2. The reversing guide 300 may include the guide rod 310 having a reversing guide surface 312 of a concave curved shape.

The guide rod 310 may extend in the second horizontal direction (Y direction) on the support plate 110. The guide rod 310 may be provided to be movable up and down relative to the second wafer Wb on the second side E2 of the support table 100.

In particular, the second driving portion 420 may include a transport rail that is provided on a backside surface opposite to a front surface of the support plate 110 facing the support table 100 and is connected to one end portion of a fixing rod 320 that fixes the guide rod 310. The fixing rod 320 may move in X, Y, and Z directions along the transport rail. The second driving portion 420 may include the transport rail as a transport mechanism, but may not be limited thereto.

As illustrated in FIG. 17, the guide rod 310 may move to a reversing position RP above the second side E2 of the support table 100 between the first position P1 and the second position P2. The roller holder 210 may move from the first position P1 to the reversing position RP by the first driving portion 410, and at least a portion of the first protective tape 20a peeled off from the first wafer Wa may slide along the reversing guide surface 312 of the guide rod 310. Accordingly, the one end portion of the first protective tape 20a peeled off from the first wafer Wa may be reversed such that the non-adhesive surface 21b of one end portion of the first protective tape 20a faces the support table 100.

Referring again to FIG. 13, the non-adhesive surface 21b of one end portion of the first protective tape 20a reversed by the reversing guide 300 may come into contact with the non-adhesive surface 21b of one end portion of the second protective tape 20b attached to the second wafer Wb on the support table 100 by the second attachment portion 230. While the non-adhesive surface 21b of one end portion of the first protective tape 20a and the non-adhesive surface 21b of one end portion of the second protective tape 20b are in contact with each other, they may be heated by the second heating block 236 to have an adhesive strength, so that one end portion of the first protective tape 20a and one end portion of the second protective tape 20b are attached to each other by a heat fusion manner.

When the non-adhesive surface 21b of one end portion of the first protective tape 20a is not reversed by the reversing guide 300 and the roller holder 210 moves to the second position P2, the adhesive surface 21a of one end portion of the first protective tape 20a may come into contact with the non-adhesive surface 21b of one end portion of the second protective tape 20b attached to the second wafer Wb by the second attachment portion 230. In this case, the adhesive layer 26 of the first protective tape 20a and the release film layer 24 of the second protective tape 20b may not be thermally fused to each other. Therefore, in order to attach one end portion of the first protective tape 20a peeled off from the first wafer Wa to one end portion of the second protective tape 20b to be peeled off, it may be necessary for the reversing guide 300 to reverse one end portion of the first protective tape 20a peeled off from the first wafer Wa.

In example embodiments, the tape peeling portion 200 may further include a peeling guide roller 219. The peeling guide roller 219 may be positioned adjacent to the roller holder 210 to guide the movement of the protective tape 20, 20a, 20b peeled from the wafer W, Wa, Wb and moved between the upper pinch roller 212a and the lower pinch roller 212b.

In this embodiment, the first attachment portion 220 and the second attachment portion 230 are provided, but it may not be limited thereto, and one attachment portion may perform the roles of both the first attachment portion 220 and the second attachment portion 230. When one attachment portion is provided, either the first attachment portion 220 or the second attachment portion 230 may be provided.

One attachment portion AT may move to the first position P1 together with the roller holder 210 to attach one end portion of the protective tape 20 between the upper pinch roller 212a and the lower pinch roller 212b to a first protective tape 20a attached to a first wafer Wa on the support table 100. In addition, one attachment portion AT may move to the second position P2 together with the roller holder 210 to attach one end portion of the first protective tape 20a between the upper pinch roller 212a and the lower pinch roller 212b to a second protective tape 20b attached to a second wafer Wb on the support table 100.

As mentioned above, the protective tape peeling apparatus 10 may include the roller holder 210 provided to be reciprocally movable between the first position P1 and the second position P2 positioned symmetrically with respect to the center of the support table 100, and having the upper pinch roller 212a and the lower pinch roller 212b, the first attachment portion 220 configured to attach one end portion of the protective tape 20 between the upper pinch roller 212a and the lower pinch roller 212b to the first protective tape 20a attached to the first wafer Wa on the support table 100 when the roller holder 210 is at the first position P1, and the second attachment portion 230 configured to attaching one end portion of the first protective tape 20a between the upper pinch roller 212a and the lower pinch roller 212b to the second protective tape 20b attached to the second wafer Wb on the support table 100 when the roller holder 210 is at the second position P2, and the reversing guide 300 configured to reverse one end portion of the first protective tape 20a between the upper pinch roller 212a and the lower pinch roller 212b such that the non-adhesive surface 21b of the first protective tape 20a faces the support table 100 when the roller holder 210 moves from the first position P1 to the second position P2.

The protective tape peeling apparatus 10 may sequentially (or continuously) peel the protective tapes 20, 20a, 20b attached to the wafers W, Wa, Wb that are sequentially provided on the support table 100 without using a separate peeling tape accessory. Accordingly, costs of the peeling tape accessories may be reduced, and/or productivity may be improved by (fully or more fully) automating the peeling operation.

Hereinafter, a method of sequentially peeling off protective tapes respectively attached to wafers using the protective tape peeling apparatus of FIG. 1 will be described.

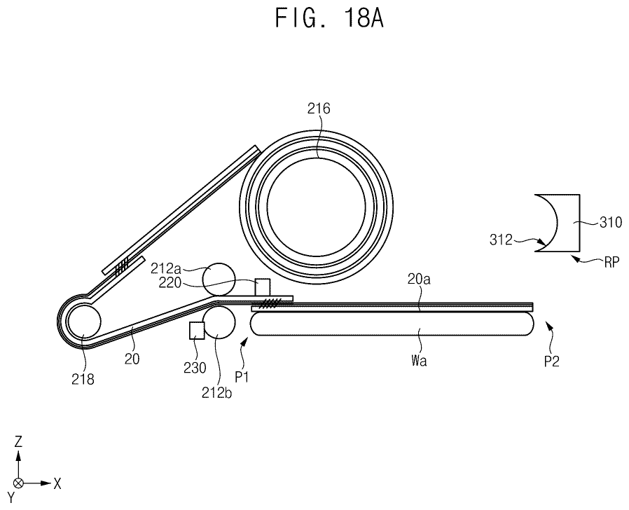

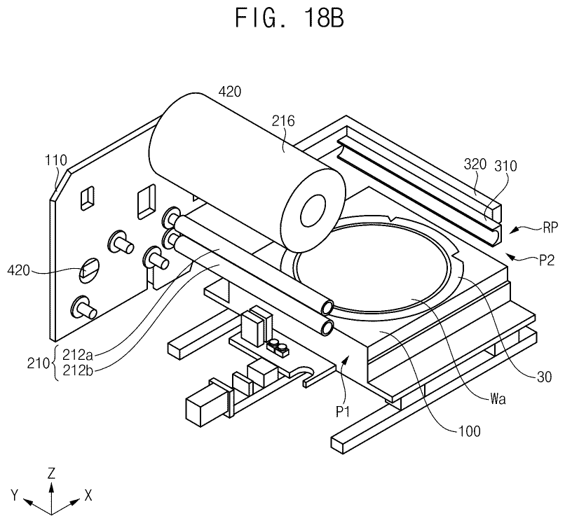

FIGS. 18A, 19A, 20A, 21A, 22A, and 23A are cross-sectional views illustrating a method of peeling off protective tapes in accordance with example embodiments. FIGS. 18B, 19B, 20B, 21B, 22B, and 23B are perspective views of FIGS. 18A, 19A, 20A, 21A, 22A, and 23A, respectively.

Referring to FIGS. 1 to 4, 10A, 10B, 18A, and 18B, first, a previously peeled protective tape 20 may be moved between an upper pinch roller 212a and a lower pinch roller 212b, and a first wafer Wa to which a first protective tape 20a is attached may be placed on a support table 100. Then, one end portion of the protective tape 20 between the upper pinch roller 212a and the lower pinch roller 212b at a first position P1 may be attached to the first protective tape 20a attached to the first wafer Wa.

In example embodiments, a roller holder 210 having the upper pinch roller 212a and the lower pinch roller 212b may be provided. The roller holder 210 may be provided to be reciprocally movable between the first position P1 on a first side E1 of the support table 100 and a second position P2 on a second side E2 opposite to the first side E1 of the support table 100.

The roller holder 210 may include the upper pinch roller 212a and the lower pinch roller 212b having a freely rotatable roll structure. The upper pinch roller 212a and the lower pinch roller 212b may move the protective tape 20 peeled off from a previous wafer W in a first direction (-X direction) while sandwiching the protective tape 20.

Then, the first wafer Wa may be attached onto a dicing tape 40 attached to a ring frame 30, and the ring frame 30 may be placed on the support table 100. The first protective tape 20a may be attached to a front surface of the first wafer Wa.

Then, the roller holder 210 may move to the first position P1, and a first attachment portion 220 may suction and press one end portion of the protective tape 20 onto one end portion of the first protective tape 20a attached to the first wafer Wa on the support table 100. At this time, a non-adhesive surface 21b of one end portion of the protective tape 20 may come into contact with a non-adhesive surface 21b of one end portion of the first protective tape 20a attached to the first wafer Wa on the support table 100. When the non-adhesive surface 21b of one end portion of the protective tape 20 and the non-adhesive surface 21b of one end portion of the first protective tape 20a are in contact with each other, one end portion of the protective tape 20 and one end portion of the first protective tape 20a may be attached to each other by a heat fusion manner.

For example, a first suction block 222 of the first attachment portion 220 may move to the first position P1 together with the roller holder 210, and the first suction block 222 may move lower than the upper pinch roller 212a to suction one end portion of the protective tape 20 and press the suctioned one end portion of the protective tape 20 onto one end portion of the first protective tape 20a attached to the first wafer Wa on the support table 100. Then, a first heating block 226 may descend within a first receiving space RS1 of the first suction block 222 to contact and heat one end portion of the protective tape 20, thereby attaching one end portion of the protective tape 20 and one end portion of the first protective tape 20a to each other in a heat fusion manner.

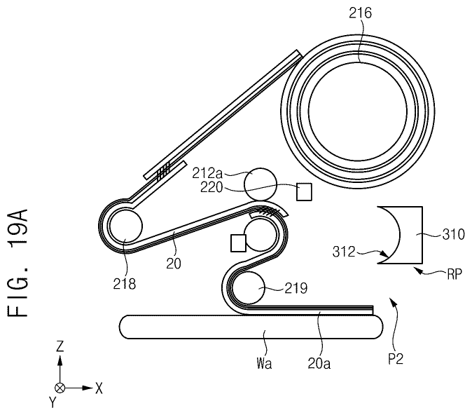

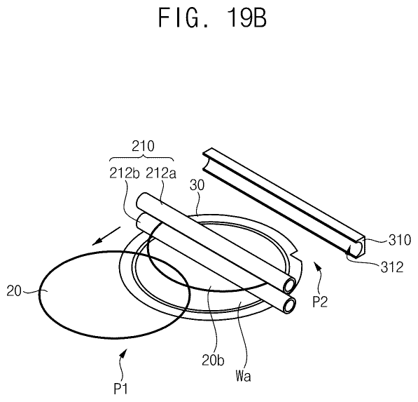

Referring to FIGS. 19A and 19B, the protective tape 20 between the upper pinch roller 212a and the lower pinch roller 212b may be moved to the second position P2 to peel the first protective tape 20a from the first wafer Wa. After one end portion of the protective tape 20 between the upper pinch roller 212a and the lower pinch roller 212b is attached to one end portion of the first protective tape 20a attached to the first wafer Wa on the support table 100 by the first attachment portion 220, the roller holder 210 may move from the first position P1 to the second position P2, thereby pulling the previously peeled protective tape 20 to peel the first protective tape 20a from the first wafer Wa. As the roller holder 210 approaches the second position P2, the peeled first protective tape 20a may move between the upper pinch roller 212a and the lower pinch roller 212b, and then may be wound around a winding roller 216.

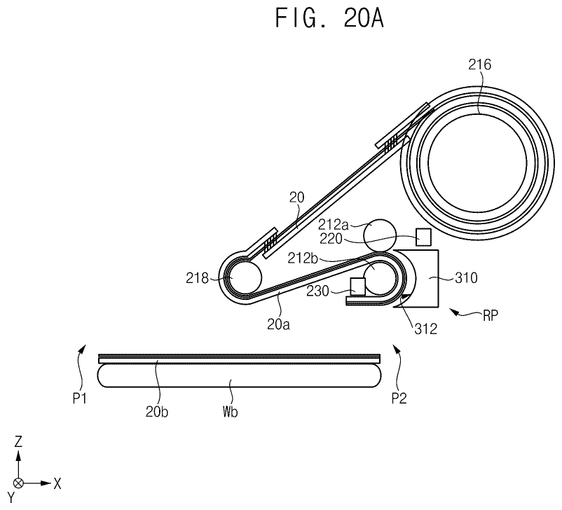

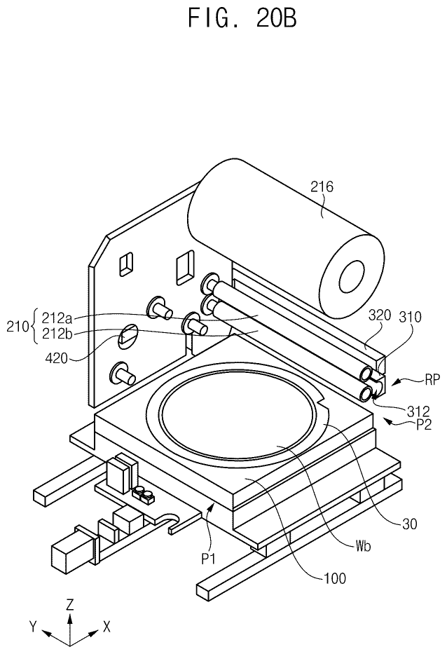

Referring to FIGS. 17, 20A, and 20B, when the protective tape 20 between the upper pinch roller 212a and the lower pinch roller 212b moves from the first position P1 to the second position P2, the non-adhesive surface 21b of one end portion of the first protective tape 20a between the upper pinch roller 212a and the lower pinch roller 212b may be reversed to face the support table 100.

As illustrated in FIG. 17, a reversing guide 300 may include a guide rod 310 having a reversing guide surface 312 of a concave curved shape. The guide rod 310 may be moved to a reversing position RP above the second side E2 of the support table 100 between the first position P1 and the second position P2. At least a portion of the first protective tape 20a peeled off from the first wafer Wa may slide along the reversing guide surface 312 of the guide rod 310. Accordingly, the non-adhesive surface 21b of one end portion of the first protective tape 20a peeled off from the first wafer Wa may be reversed to face the support table 100.

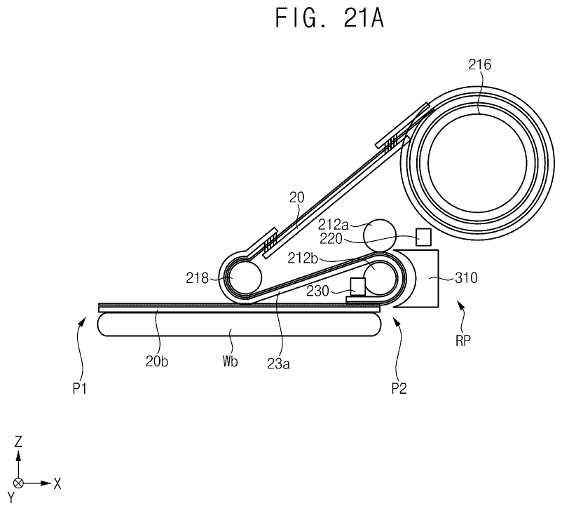

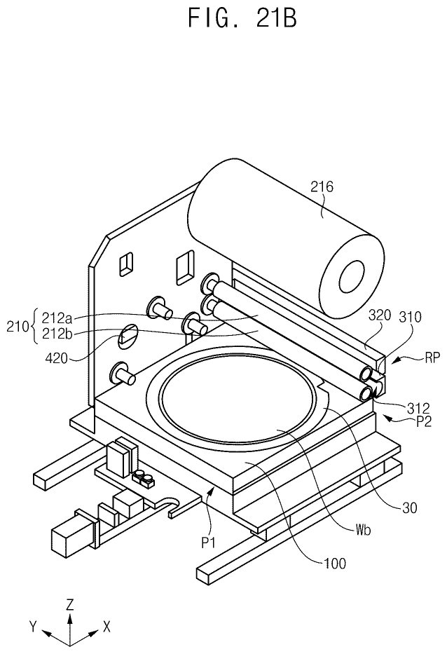

Referring to FIGS. 16A, 16B, 21A, and 21B, a second wafer Wb to which a second protective tape 20b attached may be placed on the support table 100, and one end portion of the first protective tape 20a between the upper pinch roller 212a and the lower pinch roller 212b at the second position P2 may be attached to the second protective tape 20b attached to the second wafer Wb.

In example embodiments, the second wafer Wb may be attached to a dicing tape 40 attached to a ring frame 30, and the ring frame 30 may be placed on the support table 100. The second protective tape 20b may be attached to a front surface of the second wafer Wb.

Then, the roller holder 210 may move to the second position P2, and a second attachment portion 230 may suction and press one end portion of the first protective tape 20a onto one end portion of the second protective tape 20b attached to the second wafer Wb on the support table 100. The non-adhesive surface 21b of one end portion of the first protective tape 20a reversed by the reversing guide 300 may come into contact with a non-adhesive surface 21b of one end portion of the second protective tape 20b attached to the second wafer Wb on the support table 100 by the second attachment portion 230. When the non-adhesive surface 21b of one end portion of the first protective tape 20a and the non-adhesive surface 21b of one end portion of the second protective tape 20b are in contact with each other, they may be heated by a second heater to have an adhesive effect, so that one end portion of the first protective tape 20a and one end portion of the second protective tape 20b may be attached to each other in a heat fusion manner.

For example, a second suction block 232 of the second attachment portion 230 may move to the second position P2 together with the roller holder 210, and the second suction block 232 may move lower than the lower pinch roller 212b to suction one end portion of the first protective tape 20a and press the suctioned one end portion of the first protective tape 20a onto one end portion of the second protective tape 20b attached to the second wafer Wb on the support table 100. Then, the second heating block 236 may heat one end portion of the first protective tape 20a to attach one end portion of the first protective tape 20a and one end portion of the second protective tape 20b to each other in a heat fusion manner.

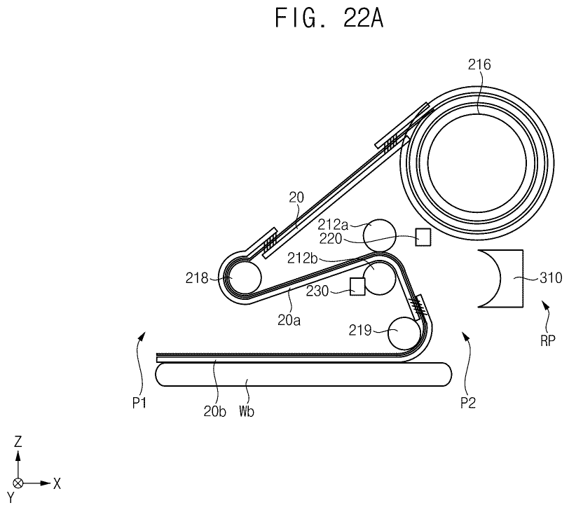

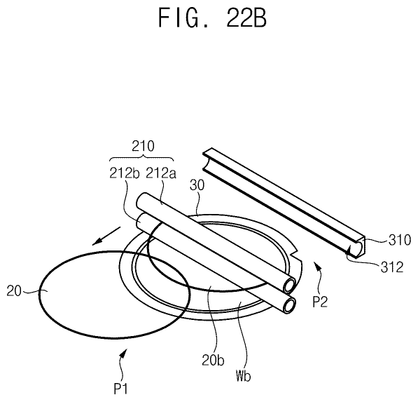

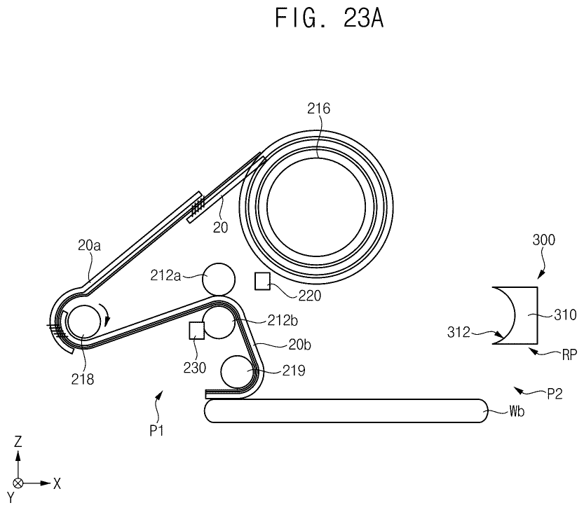

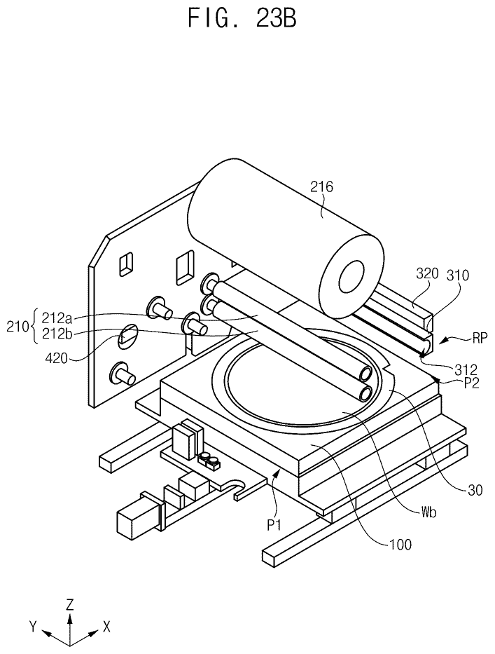

Referring to FIGS. 22A, 22B, 23A, and 23B, the first protective tape 20a between the upper pinch roller 212a and the lower pinch roller 212b may be moved to the first position P1 to peel the second protective tape 20b from the second wafer Wb. After one end portion of the first protective tape 20a between the upper pinch roller 212a and the lower pinch roller 212b is attached to one end portion of the second protective tape 20b attached to the second wafer Wb on the support table 100 by the second attachment portion 230, the roller holder 210 may move from the second position P2 to the first position P1 to pull the previously peeled first protective tape 20a to peel the second protective tape 20b from the second wafer Wb. As the roller holder 210 approaches the first position P1, the peeled second protective tape 20b may be moved between the upper pinch roller 212a and the lower pinch roller 212b, and then may be wound around the winding roller 216.

By repeatedly performing the above-described steps, the protective tapes 20, 20a, 20b attached to the wafers W, Wa, Wb that are sequentially (or continuously) provided on the support table 100 may be sequentially (or continuously) peeled without using separate peeling tape accessories.

Hereinafter, a method of dicing a substrate using the protective tape peeling apparatus and the peeling method of the protective tape described above will be described.

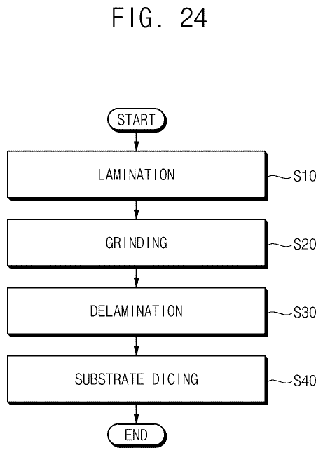

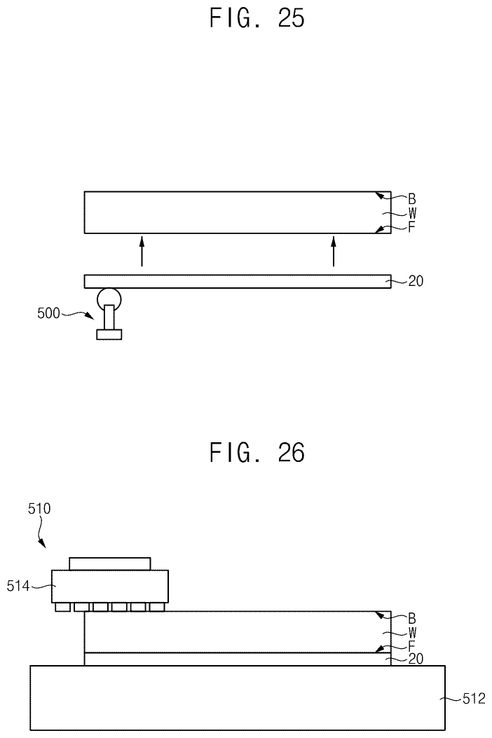

FIG. 24 is a flow chart illustrating a method of manufacturing a semiconductor package in accordance with example embodiments. FIGS. 25 to 30 are views illustrating a substrate dicing method in accordance with example embodiments.

Referring to FIGS. 24 and 25, first, a protective tape 20 for protecting circuit elements may be attached (laminated) on a first surface (active surface) F of a wafer W (S10).

As illustrated in FIG. 25, in example embodiments, the protective tape 20 may be attached to the first surface F of the wafer W using a tape attachment apparatus 500. The protective tape 20 may protect the circuit elements formed on the first surface 12 of the wafer W.

Referring to FIG. 26, a second surface (inactive surface) B of the wafer W may be ground using a grinding apparatus 510 (S20).

The wafer W may be suction-supported on a chuck table 512, and the second surface B of the wafer W may be ground using a grinder 514 to reduce a thickness of the wafer W to a desired thickness.

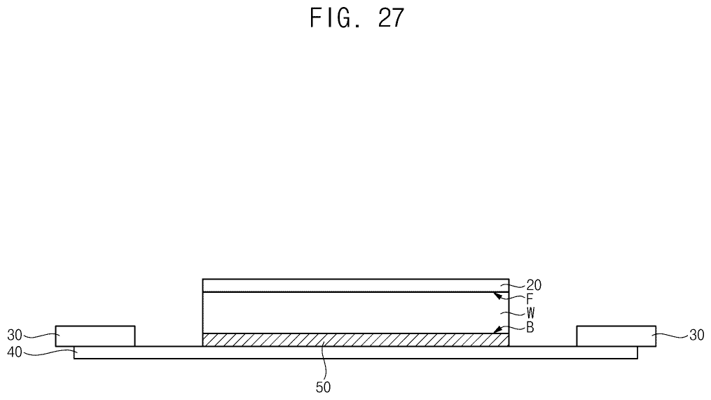

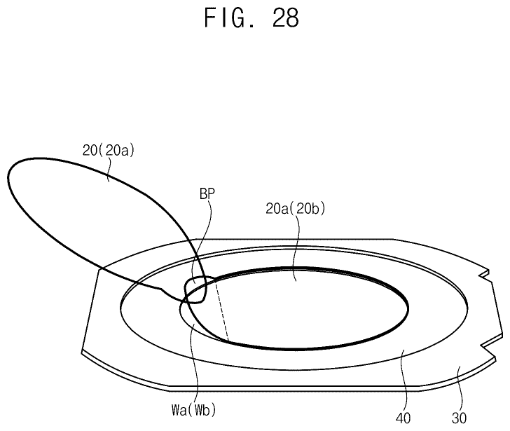

Referring to FIG. 27 and FIG. 28, the wafer W may be mounted on a ring frame 30, and the protective tape 20 may be removed from the wafer W (delamination) (S30).

As illustrated in FIG. 27, a dicing tape 40 may be attached to a lower surface of the ring frame 30, and the wafer W in which a plurality of semiconductor chips are formed may be attached on an adhesive film 50. The adhesive film 50 may be spaced apart from an inner surface of the ring frame 30. The adhesive film 50 may include a die attach film (DAF) as an organic adhesive.

Then, the protective tapes attached to the respective wafers may be sequentially peeled off using the protective tape peeling apparatus 10 of FIG. 1.

As illustrated in FIG. 28, the protective tape 20 peeled off from a previous wafer may be attached to a new first protective tape 20a to be peeled off, and the previously peeled protective tape 20 may be pulled to peel the first protective tape 20a from a new first wafer. One end portion of the protective tape 20 and one end portion of the first protective tape 20a may be thermally fused to each other to form a bonding portion BP.

Then, the first protective tape 20a peeled off from the first wafer may be attached to a new second protective tape 20b to be peeled off, and the peeled first protective tape 20a may be pulled to peel the second protective tape 20b off from a new second wafer.

Accordingly, the protective tapes attached to wafers sequentially (or continuously) provided on the support table 100 may be sequentially (or continuously) peeled off without using separate peeling tape accessories.

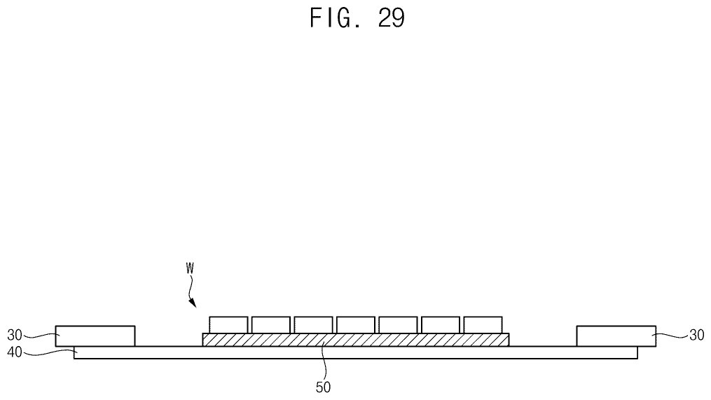

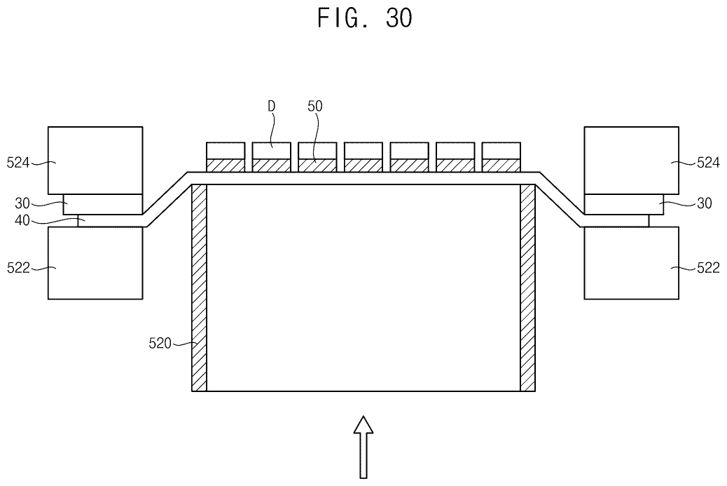

Referring to FIGS. 29 and 30, the wafer W may be cut using a blade or laser, and the dicing tape 40 may be expanded to divide the wafer W into a plurality of semiconductor chips D (S40).

As illustrated in FIG. 29, the wafer W may be cut along a scribe lane region using a blade or laser.

As illustrated in FIG. 30, the ring frame 30 and the attached portion of the dicing tape 40 may be inserted and fixedly supported between a fixing member 524 and a stage 522, and then a cylindrical pressure member 520 may be raised to expand the dicing tape 40. Accordingly, the divided chips on the dicing tape 40 may be spaced apart from each other in a radial direction. At this time, the adhesive film 50 may also be separated together.

Then, a pick-up process for picking up the individually divided semiconductor chips D may be performed. Accordingly, a semiconductor chip D to which the adhesive film 50 is attached may be attached to a package substrate or another semiconductor chip to form a semiconductor package.

A semiconductor package formed by the above protective tape peeling apparatus may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the presented embodiments. Accordingly, all such modifications are intended to be included within the scope of example embodiments as defined in the claims.

What is claimed is:

1. A protective tape peeling apparatus, comprising:
a support table configured to support wafers to which respective protective tapes are attached, the support table being configured for the wafers to be sequentially loaded on the support table;
a roller holder configured to be reciprocally moved between a first position on a first side of the support table and a second position on a second side of the support table, the second side of the support table being opposite the first side of the support table, the roller holder having an upper pinch roller and a lower pinch roller for moving a protective tape peeled off from a wafer between the upper pinch roller and the lower pinch roller;
an attachment portion configured to attach one end portion of the protective tape from between the upper pinch roller and the lower pinch roller to a first protective tape attached to a first wafer on the support table when the roller holder is at the first position, and configured to attach one end portion of the first protective tape from between the upper pinch roller and the lower pinch roller to a second protective tape attached to a second wafer on the support table when the roller holder is at the second position; and
a reversing guide configured to reverse the one end portion of the first protective tape between the upper pinch roller and the lower pinch roller such that a non-adhesive surface of the first protective tape faces the support table when the roller holder moves from the first position to the second position.

2. The protective tape peeling apparatus of claim 1, wherein the attachment portion includes:
a suction portion configured to apply suction to the one end portion of the protective tape; and
a heater configured to heat the one end portion of the protective tape.

3. The protective tape peeling apparatus of claim 1, wherein the attachment portion includes:
a suction portion configured to apply suction to the one end portion of the protective tape; and
an ultrasonic generator configured to heat to the one end portion of the protective tape.

4. The protective tape peeling apparatus of claim 1, wherein the upper pinch roller and the lower pinch roller have a freely rotatable roll structure.

5. The protective tape peeling apparatus of claim 1, further comprising:
a peeling guide roller configured to guide movement of the protective tape that is peeled from the wafer and moves between the upper pinch roller and the lower pinch roller.

6. The protective tape peeling apparatus of claim 1, wherein the reversing guide includes a guide rod having a reversing guide surface of a concave curved shape for contacting at least a portion of the first protective tape moved between the upper pinch roller and the lower pinch roller.

7. The protective tape peeling apparatus of claim 6, wherein the at least a portion of the first protective tape slides along the reversing guide surface such that the one end portion of the first protective tape is reversed, when the first protective tape moves between the upper pinch roller and the lower pinch roller.

8. The protective tape peeling apparatus of claim 1, further comprising:
a winding roller configured to wind the protective tape supplied from the roller holder into a roll form.

9. The protective tape peeling apparatus of claim 8, further comprising:
a tension roller configured to generate a tensile force and move the protective tape between the roller holder and the winding roller.

10. The protective tape peeling apparatus of claim 1, further comprising:
a first driving portion configured to reciprocally move the roller holder between the first position and the second position; and
a second driving portion configured to move the reversing guide upward and downward between a reversing position and the second position, the reversing position being between the first position and the second position.

11. A protective tape peeling apparatus, comprising:
a support table configured to support wafers that are sequentially placed and to which respective protective tapes are attached on the wafers;
a tape peeling portion including a roller holder having an upper pinch roller and a lower pinch roller configured to move a protective tape peeled from a previous wafer in a first direction, a first attachment portion configured to attach one end portion of the protective tape moving between the upper pinch roller and the lower pinch roller to one end portion of a first protective tape attached to a first wafer on the support table, and a second attachment portion configured to attach one end portion of the first protective tape peeled from the first wafer and moving between the upper pinch roller and the lower pinch roller to one end portion of a second protective tape attached to a second wafer on the support table;
a reversing guide configured to reverse one end portion of the first protective tape peeled off from the first wafer such that a non-adhesive surface of one end portion of the first protective tape faces the support table;
a first driving portion configured to reciprocally move the tape peeling portion between a first position on a first side of the support table and a second position on a second side of the support table, the second side of the support table being opposite the first side of the support table; and
a second driving portion configured to move the reversing guide upward and downward on the second side of the support table.

12. The protective tape peeling apparatus of claim 11, wherein the first attachment portion and the second attachment portion each include:
a suction block configured to apply suction to the one end portion of the protective tape; and
a heating block configured to heat the one end portion of the protective tape.

13. The protective tape peeling apparatus of claim 12, wherein the heating block includes a heater or an ultrasonic generator.

14. The protective tape peeling apparatus of claim 11, wherein the upper pinch roller and the lower pinch roller have a freely rotatable roll structure.

15. The protective tape peeling apparatus of claim 11, wherein the tape peeling portion further includes a peeling guide roller configured to guide movement of the protective tape that is peeled from the previous wafer and moves between the upper pinch roller and the lower pinch roller.

16. The protective tape peeling apparatus of claim 11, wherein the reversing guide includes a guide rod having a reversal guide surface of a concave curved shape for contacting at least a portion of the first protective tape peeled off from the first wafer.

17. The protective tape peeling apparatus of claim 16, wherein
the second driving portion is configured to raise the guide rod between the first position and the second position to a reversing position above the second side of the support table, and
the first driving portion is configured to move the roller holder to the reversing position such that at least a portion of the first protective tape slides along the reversing guide surface.

18. The protective tape peeling apparatus of claim 11, further comprising:
a winding roller configured to wind the protective tape supplied from the roller holder into a roll form.

19. The protective tape peeling apparatus of claim 18, further comprising:
a tension roller configured to generate a tensile force and move the protective tape between the roller holder and the winding roller.

20. The protective tape peeling apparatus of claim 11, further comprising:
a ring frame on the support table; and
a dicing tape attached to the ring frame for having a wafer attached on the dicing tape.
